(19) United States
(12) Patent Application Publication
(10) Pub. No.: US 2010/0312494 A1
(43) Pub. Date: Dec. 9, 2010

(54) PROCESS AND APPARATUS FOR TESTING A COMPONENT USING AN OMNI-DIRECTIONAL EDDY CURRENT PROBE

(76) Inventors: Sanghamithra Korukonda, Malleswaram (IN); Sandeep Dewangan, Karnataka (IN); William Stewart McKnight, Hamilton, OH (US); Gigi Gambrell, West Chester, OH (US); Changting Wang, Schenectady, NY (US); Ui Suh, Cincinnati, OH (US)

Correspondence Address: General Electric Company;GE Global Patent Operation, 2 Corporate Drive, Suite 648, Shelton, CT, 06484, US

(21) Appl. No.: 12/810,597

(22) PCT Filed: Dec. 28, 2007
(86) PCT No.: PCT/IN2007/000609

§ 371 Date: Aug. 23, 2010

(51) Int. Cl. G01N 27/90; G06F 19/00; G01R 35/00

(52) U.S. Cl. 702/38; 702/104; 324/202

(57) ABSTRACT

A method for testing a component using an eddy current array probe is provided. The method includes calibrating the eddy current array probe, collecting data from the eddy current array probe for analysis, and processing the collected data to at least one of compensate for response variations due to a detected orientation of a detected imperfection and to facilitate minimizing noise.

### BACKGROUND OF THE INVENTION

The field of the invention relates generally to non-destructive testing of components, and more particularly to methods and apparatus for non-destructive testing components using an omni-directional eddy current (EC) probe.

EC inspection devices may be used to detect abnormal indications in a component under test such as, but not limited to, a gas turbine engine component. For example, known EC inspection devices may be used to detect cracks, dings, raised material, and/or other imperfections on a surface and/or within the component. EC inspection devices may also be used to evaluate material properties of the component including the conductivity, density, and/or degrees of heat treatment that the component has encountered.

EC images are typically generated by scanning a part surface with a single element EC coil. An imperfection on, or within, the part surface is detected by the EC element when it traverses the complete extent of the imperfection. At least some known eddy current array probe (ECAP) imaging, however, consists of an array of EC elements that scan the surface of a part in one direction. Using an array of EC elements reduces inspection time and increases inspection speed when compared to a single EC element scan. However, ECAP images require processing prior to flaw detection. Specifically, processing is necessary because an imperfection detected during a scan using ECAP may be seen only in partial by several EC element coils, rather than being seen completely by only one EC element coil as occurs with single-coil EC imaging.

In addition, the use of known EC probes may be limited by the fact that a prior knowledge of crack orientation is required. Because of the directionality of differential eddy current probes, if more than one flaw orientation is anticipated, the test specimen may require repeated scanning in different orientations to detect the flaws. Such repeated scanning is time consuming and may be inefficient.

### BRIEF DESCRIPTION OF THE INVENTION

In one embodiment, a method for testing a component using an eddy current array probe is described. The method includes calibrating the eddy current array probe, collecting data from the eddy current array probe for analysis, and processing the collected data to at least one of compensate for response variations due to a detected orientation of a detected imperfection and to facilitate minimizing noise.

In another embodiment, an eddy current flaw detection system is described. The flaw detection system includes an eddy current array probe and a processing device coupled to the eddy current array probe. The processing device is configured to collect data from the eddy current array probe and compensate collected data for varying orientations of detected imperfections.

In another embodiment, an eddy current array probe calibration device is described. The calibration device includes a plurality of test notches oriented in a plurality of rows and columns, wherein adjacent rows are separated by a predetermined distance, and wherein adjacent columns are separated by a predetermined distance. The calibration device also includes a voltage measuring device configured to measure a sensed voltage detected by the eddy current array probe at each of the plurality of notches.

In another embodiment, a method of calibrating an eddy current array probe is described. The method includes positioning a plurality of notches in a predetermined manner on a test block, measuring a voltage sensed by the eddy current array probe for each of said plurality of notches, and setting a gain of the eddy current array probe based on the measured voltage.

### BRIEF DESCRIPTION OF THE DRAWINGS

FIG. 1 is a schematic diagram of an exemplary eddy current surface flaw detection system;

FIG. 2 is a schematic diagram of an exemplary eddy current array probe;

FIG. 3 is a block diagram illustrating an exemplary layout of a calibration block;

FIG. 4 is a plan view of an exemplary component that includes a plurality of exemplary defects that may be detected during an EC inspection;

FIG. 5 is an exemplary flow chart of an automated defect recognition (ADR) process for use with an omni-directional EC array probe;

FIG. 6 is an exemplary plot of output data that corresponds to a circumferential defect detected using an omni-directional EC probe;

FIG. 7 is an exemplary plot of output data that corresponds to a radial defect detected using an omni-directional EC probe; and

FIG. 8 is a graphical representation of exemplary data obtained from a sample including a defect, a plot of a raw test image, a plot of the raw test image after compensation, and a plot of the raw test image after compensation, as compared to a threshold value.

### DETAILED DESCRIPTION OF THE INVENTION

In one embodiment, an automated defect recognition (ADR) process for a Wide Area Standard Probe (WASP) is described herein. The WASP is a type of eddy current inspection probe that facilitates an efficient and productive inspection process through the use of a multi-element scan. A unique advantage of the WASP is its ability to detect flaws in substantially any orientation, such that a limited amount of data is obtained in comparison to other known eddy current probes. However, the benefits gained through the acquisition of a limited amount of data, may be offset by the reliability of inspections completed with such probes.

In an exemplary embodiment, the ADR process automates the entire data processing procedure. The ADR method also facilitates reliable flaw recognition and characterization, while minimizing false defect identification. In the exemplary embodiment, signal processing algorithms are used to identify potential defect signals from the WASP inspection data and to estimate the size and orientation of the defects. The algorithms establish criteria used to estimate the orientation of the defect and to apply appropriate corrections in order to facilitate maximizing the response from the defect. In addition, the algorithms may function without the use of reference images, look-up-tables, or any other a priori information.

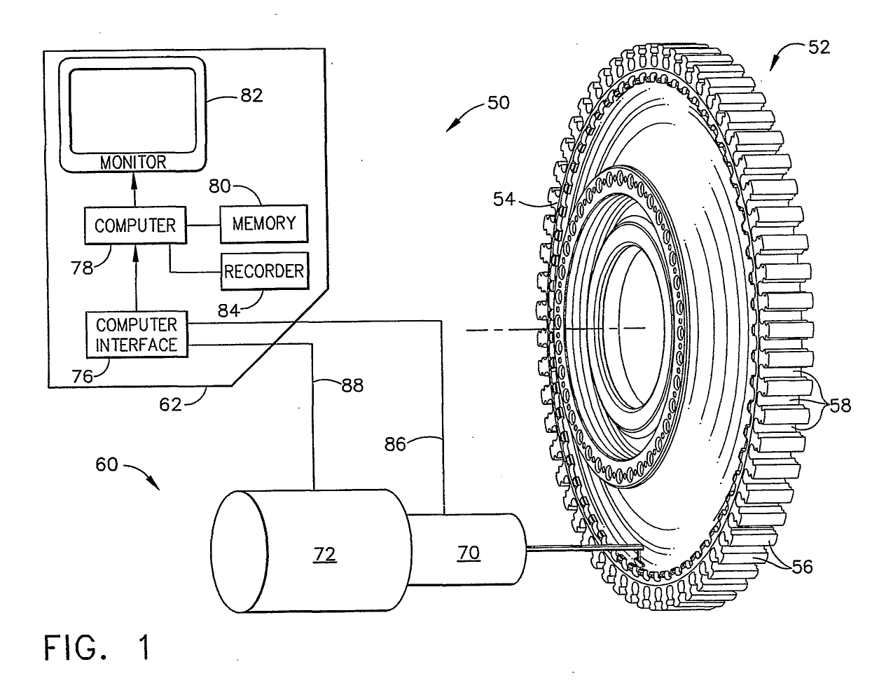

FIG. 1 is a schematic diagram of an exemplary eddy current flaw detection system 50 that may be used to inspect a component 52 such as, but not limited to, a gas turbine engine disk 54. In the exemplary embodiment, disk 54 includes a plurality of dovetail posts 56 and a plurality of circumferentially-spaced dovetail slots 58 defined between adjacent pairs of posts 56.

Although the methods and apparatus herein are described with respect to posts 56 and dovetail slots 58, it should be appreciated that the methods and apparatus can be applied to a wide variety of components. For example, the present invention may be used with component 52 of any operable shape, size, and/or configuration. Examples of such components may include, but are not limited to only including, components of gas turbine engines such as seals, flanges, turbine blades, turbine vanes, and/or flanges. The component may be fabricated of any base material such as, but not limited to, nickel-base alloys, cobalt-base alloys, titanium-base alloys, iron-base alloys, and/or aluminum-base alloys. More specifically, although the methods and apparatus herein are described with respect to aircraft engine components, it should be appreciated that the methods and apparatus can be applied to, or used to inspect, a wide variety of components used within a steam turbine, a nuclear power plant, an automotive engine, or any other mechanical components.

In the exemplary embodiment, detection system 50 includes a probe assembly 60 and a data acquisition/control system 62. Probe assembly 60 includes an eddy current (EC) coil/probe 70 and a probe manipulator 72 that is coupled to probe 70. Eddy current probe 70 and probe manipulator 72 are each electrically coupled to data acquisition/control system 62 such that control/data information can be transmitted to/from EC probe 70 and/or probe manipulator 72 and/or data acquisition/control system 62. In an alternative embodiment, system 50 also includes a turntable (not shown) that selectively rotates component 52 during the inspection procedure.

Data acquisition/control system 62 includes a computer interface 76, a computer 78, such as a personal computer with a memory 80, and a monitor 82. Computer 78 executes instructions stored in firmware (not shown), and is programmed to perform functions described herein. As used herein, the term “computer” is not limited to just those integrated circuits referred to in the art as computers, but rather broadly refers to computers, processors, microcontrollers, microcomputers, programmable logic controllers, application specific integrated circuits, and other programmable circuits, and these terms are used interchangeably herein.

Memory 80 is intended to represent one or more volatile and/or nonvolatile storage facilities that shall be familiar to those skilled in the art. Examples of such storage facilities often used with computer 78 include, but are not limited to, solid-state memory (e.g., random access memory (RAM), read-only memory (ROM), and flash memory), magnetic storage devices (e.g., floppy disks and hard disks), and/or optical storage devices (e.g., CD-ROM, CD-RW, and DVD). Memory 80 may be internal to, or external from, computer 78. Data acquisition/control system 62 also includes a recording device 84 such as, but not limited to, a strip chart recorder, a C-scan, and/or an electronic recorder that is electrically coupled to either computer 78 and/or eddy current probe 70.

In use, a component 52, such as disk 54, is mounted on a fixture (not shown) that secures the component 52 in place during inspection. Eddy current probe 70 is selectively positioned within dovetail slots 58 to facilitate enabling substantially all of the interior of dovetail slots 58 to be scanned during inspection. In the exemplary embodiment, probe manipulator 72 is a six-axis manipulator. EC probe 70 generates electrical signals in response to the eddy currents induced within the surface of dovetail slots 58 during scanning of dovetail slots 58 by probe 70. Electrical signals generated by EC probe 70 are received by data acquisition/control system 62 via a data communications link 86 and are stored in memory 80 and/or recorder 84. Computer 78 is also coupled to probe manipulator 72 by a communications link 88 to facilitate controlling the scanning of disk 54. A keyboard (not shown) is electrically coupled to computer 78 to facilitate operator control of the inspection of disk 54. In the exemplary embodiment, a printer (not shown) may be provided to generate hard copies of the images generated by computer 78.

In the exemplary embodiment, system 50 may be used to perform any kind of eddy current inspection, such as conventional inspection, single-coil inspection, or array probe inspection. System 50 automatically scans the surface of component 52 and stores the acquired data in the form of images. The defect recognition algorithms will then be employed by computer 78 to identify and characterize any flaw (if present) on the surface of component 52.

When an eddy current (EC) test is performed, a magnetic field is generated by a drive coil. Such generation may include, but is not limited to only, supplying an alternating current to a drive coil. The drive coil is positioned adjacent to a surface of a component to be tested. When the drive coil is positioned, the drive coil is oriented substantially parallel to the surface being tested. Such an orientation of the drive coil causes the magnetic field generated by the drive coil to be oriented substantially normal to the surface being tested.

A sensor is coupled to the drive coil to receive secondary fields. Secondary fields of interest are received at the sensor after the magnetic fields generated by the drive coil are reflected from a surface flaw on, or in, the surface being tested. The sensor is configured to convert the reflected secondary field into an electric signal that may be viewed and/or recorded.

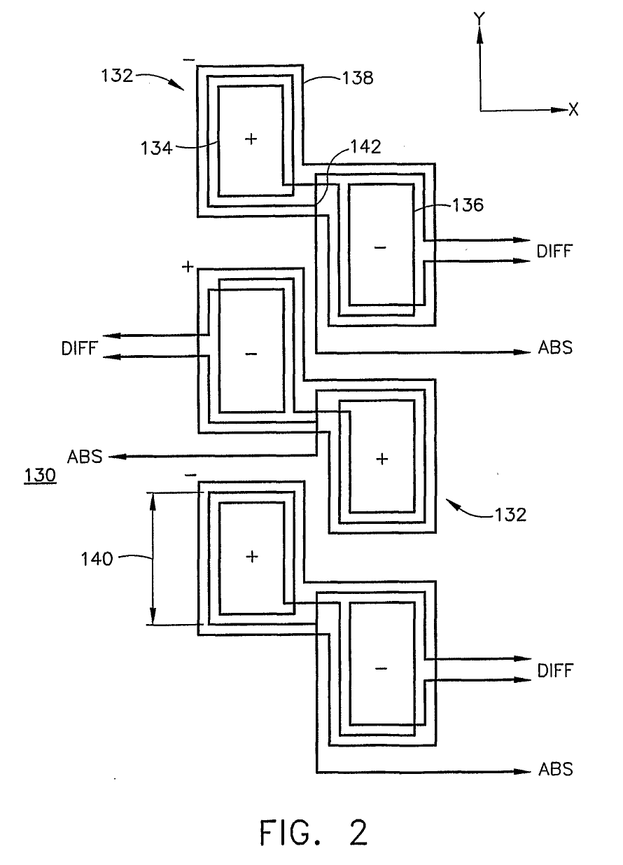

FIG. 2 illustrates an exemplary embodiment of an omni-directional eddy current (EC) probe 130. Omni-directional EC probe 130 includes at least one EC channel 132. In the exemplary embodiment, EC channel 132 includes a first sense coil 134 and a second sense coil 136. First and second sense coils 134 and 136 are offset from one another in a first (X) and a second (Y) direction and overlap one another in at least one of the first and second directions (X,Y). As used herein, the terms “offset” and “overlap” are not mutually exclusive. For example, in the exemplary embodiment, first and second sense coils 134 and 136 are both offset and overlap in the Y direction. In other words, for this orientation, first and second sense coils 134 and 136 are partially offset in the (Y) direction, whereas they are completely offset (i.e., with no overlap) in the (X) direction. In one embodiment, first and second sense coils 134 and 136 overlap in second direction (Y) by at least about twenty-five percent (25%) of a length 140 of the sense coils 134 and 136. In another embodiment, the first and second sense coils 134 and 136 overlap in the second direction (Y) by at least about thirty-three percent (33%) of the length 140 of sense coils 134 and 136. In another embodiment, first and second sense coils 134 and 136 overlap in second direction (Y) by at least about fifty percent (50%) of length 140 of sense coils 134 and 136.

Omni-directional EC probe 130 also includes at least one drive coil 138 that generates a probing field for EC channel 132 in a vicinity of first and second sensing coils 134 and 136. In the exemplary embodiment, drive coil 138 extends around first and second sense coils 134 and 136 and forms EC channel 132.

To enhance scanning of a relatively large surface area, an array of EC channels 132 is employed. Accordingly, the exemplary omni-directional EC probe 130 includes a number of EC channels 132 and a number of drive coils 138. Specifically, in the exemplary embodiment, at least one drive coil 138 is provided for each EC channel 132.

In the exemplary embodiment, the overlapping orientation of first and second sense coils 134 and 136 enables omni-directional EC probe 130 to detect imperfections in a sample being tested anywhere along the (Y) direction. However, omni-directional EC probe 130 may include any orientation of EC channels 132 that enables EC probe 130 to function as described herein. By including a plurality of EC channels 132 that are substantially identical, performance of the plurality of EC channels 132 is facilitated to be substantially uniform.

As described above with respect to EC probe 70, omni-directional EC array probe 130 is used to detect surface, or near surface, cracks (i.e., surface connected flaws) in conductive components, such as, but not limited to, aircraft engine components including disks, spools, and blades. Exemplary components are formed of nickel alloys and titanium alloys. However, EC probe 130 may be used with a variety of conductive components.

Operationally, drive coil 138 excites and generates a magnetic flux (i.e., probing field). The magnetic field influx into a conductive test object (not shown in FIG. 1) generates an eddy current on the surface of the test object, which in turn generates a secondary magnetic field. In case of a surface flaw (not shown), the secondary magnetic field deviates from its normal orientation, to a direction corresponding to the flaw orientation. This deviated secondary magnetic field induces corresponding signals (i.e., sense signals) in the sense coils 134 and 136 which are indicative of the presence of the surface flaw. In the exemplary embodiment, because of the offset in two directions (i.e., X and Y directions), the differential coupling of sense coils 134 and 136 enables the directional deviation in the secondary magnetic flux corresponding to any crack orientation to be detected. More specifically, sense coils 134 and 136 impart an omni-directional sensitivity to EC probe 130. In addition, the overlap orientation of sense coils 134 and 136 in the Y direction facilitates complementary sensing while scanning the surface of a test object with the probe in the X direction.

In the exemplary embodiment, first sense coil 134 has a positive polarity and second sense coil 136 has a negative polarity. The exemplary omni-directional EC probe 130 also includes electrical connections 142 that electrically couple first and second sense coils 134 and 136 together. In one embodiment, the electrical connections 142 are configured to perform both differential sensing (indicated by “DIFF”) and absolute sensing (indicated by “ABS”). Beneficially, the inclusion of both differential and absolute sensing features facilitates the detection of both small and long cracks.

First and second sense coils 134 and 136 form each EC channel 132 and have opposite polarity (indicated by “+” and “−”), and electrical connections 142 electrically couple first and second sense coils 134 and 136 within each respective EC channel 132. Drive coils 138 have alternating polarity with respect to adjacent drive coils 138 (also indicated by “+” and “−”). The polarity of first and second sense coils 134 and 136 alternates correspondingly with respect to adjacent EC channels. For example, those sense coils 134 and 136 within the middle EC channel 132 have the opposite polarity relative to those sense coils 134 and 136 in the upper and lower EC channels 132.

In an alternative embodiment, each EC channel 132 includes a sensor. For example, in one embodiment, the sensor is a solid-state sensor, such as, but not limited to, a Hall sensor, an anisotropic magnetic resistor (AMR), a giant magnetic resistor (GMR), a tunneling magnetic resistor (TMR), an extraordinary magnetoresistor (EMR), and/or a giant magnetoimpedance (GMI). However, any unpackaged solid-state sensor that enables eddy current testing as described herein may be used.

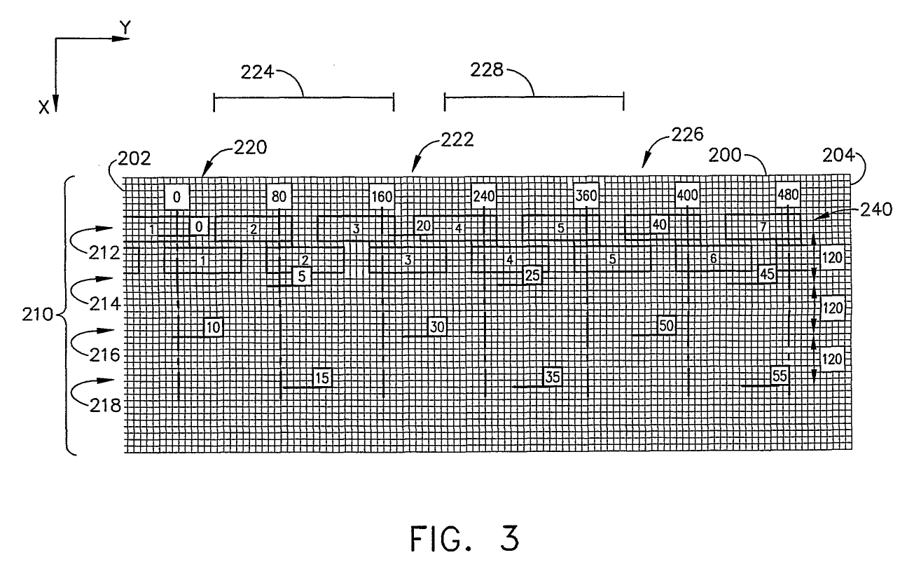

FIG. 3 is a block diagram illustrating an exemplary layout a calibration block 200 that may be used to calibrate an omni-directional EC array probe, for example, omni-directional EC array probe 240. In one embodiment, EC array probe 240 is substantially similar to EC array probe 130 (shown in FIG. 2). In the exemplary embodiment, calibration block 200 includes a first edge 202, and a second edge 204, and a plurality of test notches 210. More specifically, in the exemplary embodiment, the plurality of test notches 210 include multiple rows of test notches. For example, in the exemplary embodiment, test notches 210 include a first row of notches 212, a second row of notches 214, a third row of notches 216, and a fourth row of notches 218. Each row 212, 214, 216, and 218 includes a plurality of individual notches. More specifically, in the exemplary embodiment, each row 212, 214, 216, and 218 includes a first notch 220 positioned adjacent first edge 202. Each row 212, 214, 216, and 218 also includes a second notch 222 positioned a predetermined distance 224 in the Y direction from first notch 220, and a third notch 226 positioned a predetermined distance 228 in the Y direction from second notch 222. The placement of the notches ensures that consistent reference voltage is obtained, regardless of where probe coils are located at different notches.

An omni-directional EC array probe 240 is initially positioned on calibration block 200. Probe 240 is then calibrated by moving probe 240 relative to calibration block 200 while measuring a voltage detected by the sensing coils (shown in FIG. 2) as the sensing coils pass over notches 210. Specifically, the detected voltage is measured at each notch 210. With the detected voltages, a single instrument gain is set based on the maximum notch response, independent of EC channel (shown in FIG. 2). Once the gain is set, normalization factors are used to insure a uniform response across the sensing coils. The calculated gain settings produced with calibration block 200 facilitate increasing the accuracy of the acquired data when compared to a non-calibrated EC array probe.

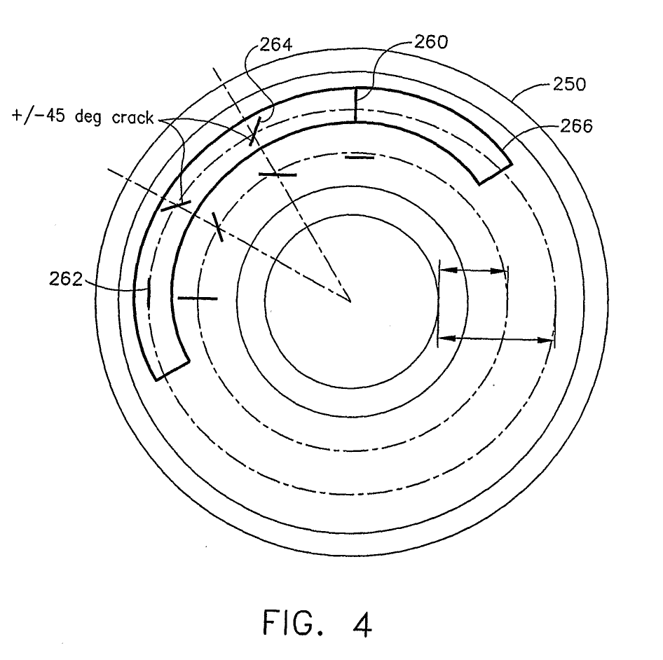

FIG. 4 is a plan view of an exemplary component 250 that includes a plurality of exemplary defects. For example, in the exemplary embodiment, component 250 includes a radial defect 260, a circumferential defect 262, and an angled defect 264. Radial defect 260, circumferential defect 262, and angled defect 264 are examples of different defect orientations that may occur within component 250. An exemplary EC probe path is illustrated at 266. As described in more detail below, radial defect 260, circumferential defect 262, and angled defect 264 respond differently to EC array probe 240, in terms of a maximum amplitude of the response and a signature of the response.

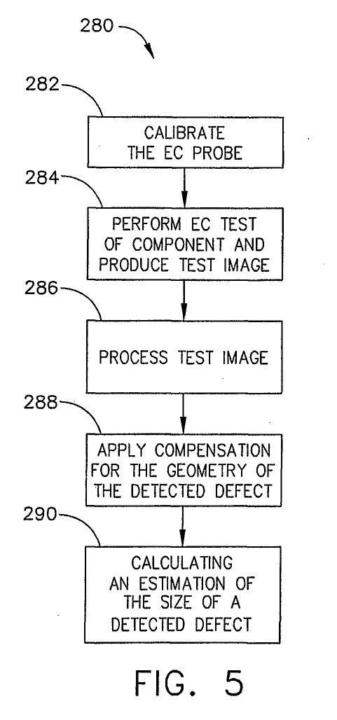

FIG. 5 is an exemplary flow chart of an automated defect recognition (ADR) process 280 that may be used with an omni-directional EC array probe, such as EC array probe 240 (shown in FIG. 3). In an exemplary embodiment, ADR process 280 is performed via a processing device (not shown in FIG. 5). As used herein, the term “processing device” is not limited to just those integrated circuits referred to in the art as a processing device, but broadly refers to, a processor, a microprocessor, a controller, a microcontroller, a programmable logic controller, an application specific integrated circuit, and other programmable circuits. ADR process 280 facilitates accurate flaw recognition and characterization while limiting false identifications of defects. In one embodiment, ADR process 280 is performed by EC flaw detection system 50 (shown in FIG. 1). ADR process 280 includes calibrating 282 the EC array probe. The response of the EC array probe to a defect varies depending on the location of the EC array probe that senses the defect. Calibrating 282 may include determining a probe gain that provides a consistent response of detected defects across the EC array probe. Moreover, calibrating 282 may be accomplished using a calibration block, such as, calibration block 200 (shown in FIG. 3), for example.

ADR process 280 also performs 284 an EC test of the component and produces a test image (not shown in FIG. 5). The test image produced represents a plot of detected voltages over a distance or location of the EC array probe relative to the component surface. Processing 286 the test image produces a processed test image (not shown in FIG. 5). In the exemplary embodiment, during processing 286, a wavelet decomposition is used to facilitate improving small crack detection, and improving the probability of detection (PoD). PoD is a measurement of, for example, the ability of a non-destructive test to identify an imperfection of a known size within a component.

More specifically, in the exemplary embodiment, an algorithm decomposes the raw test image into various frequency sub-bands in the wavelet domain. The sub-bands are then subjected to a plurality of noise filters and adaptive thresholds, that are customized to the signal content of the sub-band under consideration. The use of appropriate sub-bands enhances the flaw response signature and thereby facilitates improving detectability and reducing the possibilities of false positives as compared to applying conventional rigid threshold segmentation schemes on the raw test data. ADR process 280 also includes compensating 288 the processed test image to correct for various signal levels detected, depending on the geometry of the detected defect.

ADR process 280 also includes calculating 290 an estimation of the size of a detected defect. The estimation of the size of the detected defect is based on the processed test image after compensating 288 which provides for higher accuracy of the size estimate while limiting false indications of a defect. The estimation of the size of the detected defect is then compared to a threshold value. If the estimated size of the detected defect is higher than the threshold value, a defect is noted. If the estimation of the size of the detected defect is lower than the threshold value, no defect is noted. Threshold values are calculated by PoD analysis.

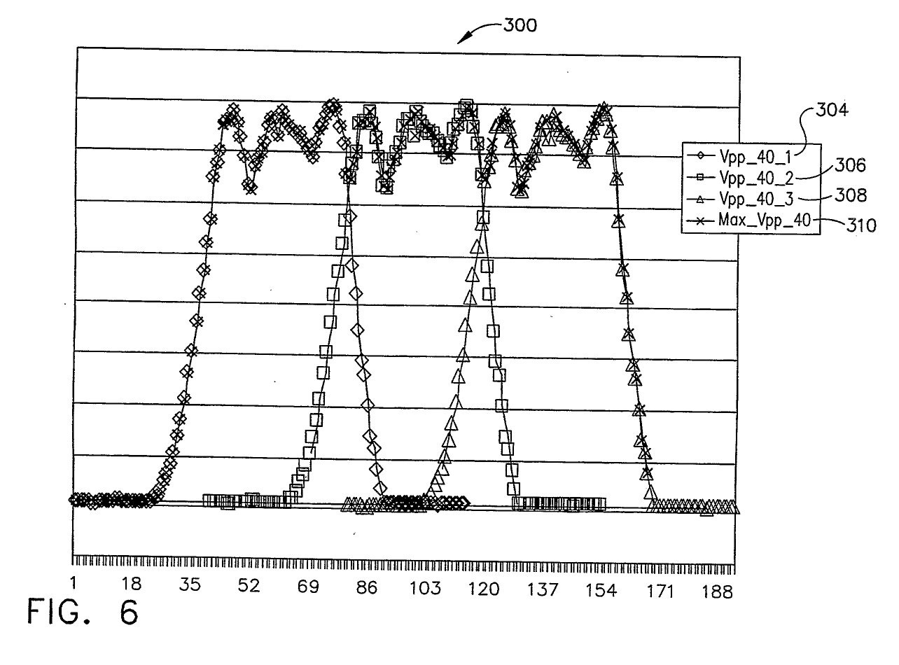

FIG. 6 is a plot 300 of an exemplary data output from an exemplary omni-directional EC probe, such as EC array probe 240 (shown in FIG. 3). Specifically, plot 300 includes a plot 304 of a first peak-to-peak voltage (Vpp), a plot 306 of a second Vpp, and a plot 308 of a third Vpp. First plot 304, second plot 306, and third plot 308 illustrate an output of an omni-directional EC probe as the probe detects a circumferential defect 262 (shown in FIG. 4). In the exemplary embodiment, three coils are used to detect circumferential defect 262, and to collect output data to produce first plot 304, second plot 306, and third plot 308.

In the exemplary embodiment, compensating 288 (shown in FIG. 5) the processed test image to correct for the various signal levels detected includes calculating a maximum Vpp 310 from first plot 304, second plot 306, and third plot 308 when the test image indicates the presence of a circumferential defect. Maximum Vpp 310 enables a maximum response to be extracted from the data provided by the omni-directional EC probe.

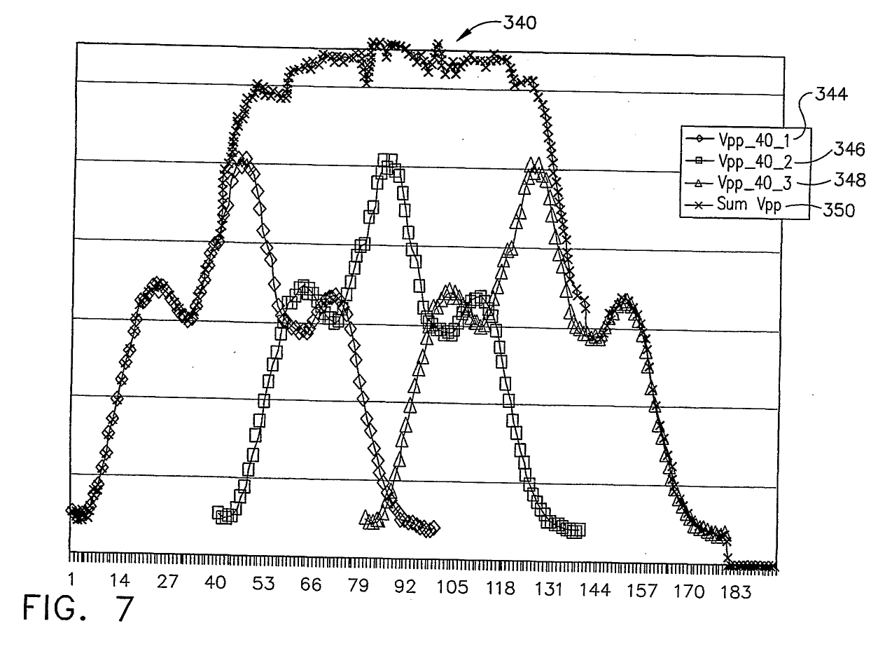

FIG. 7 is an exemplary plot 340 of exemplary data output from an exemplary omni-directional EC probe, such as probe 240 (shown in FIG. 3). Plot 340 includes a plot 344 of a first Vpp, a plot 346 of a second Vpp, and a plot 348 of a third Vpp. First plot 344, second plot 346, and third plot 348 illustrate an output of an omni-directional EC probe as the probe detects a radial defect 260 (shown in FIG. 4). In the exemplary embodiment, three coils are used to detect radial defect 260, and to collect output data to produce first plot 344, second plot 346, and third plot 348.

In the exemplary embodiment, compensating 288 (shown in FIG. 5) the processed test image to correct for the various signal levels detected includes calculating a sum 350 from first plot 344, second plot 346, and third plot 348 when the test image indicates the presence of a radial defect. Sum 350 enables a maximum response to be extracted from the data provided by the omni-directional EC probe.

Compensating 288 corrects partial defect responses, such as, for example, plot 344 of first Vpp, plot 346 of second Vpp, and plot 348 of third Vpp, so as to produce one single maximum defect response, for example, maximum Vpp 310 and sum 350. As described above, maximum Vpp 310 and sum 350 are used to predict the size of the defect.

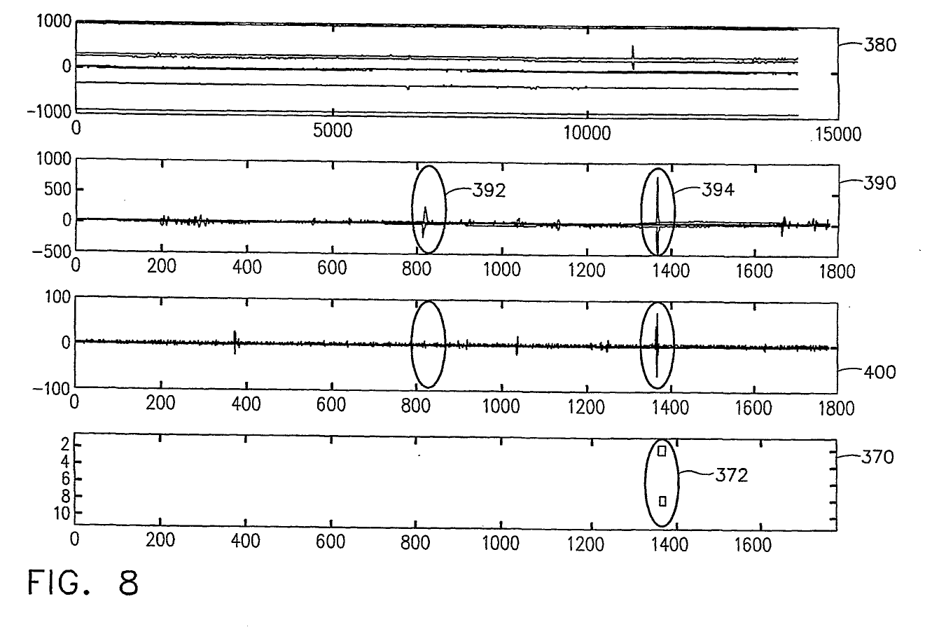

FIG. 8 is a graphical illustration of a component to be tested 370 including a defect 372, a plot 380 of a raw test image, a plot 390 of the raw test image after compensation, and a plot 400 of the raw test image after compensation and comparison to a threshold value. In an exemplary embodiment, plot 380 is created from data obtained by omni-directional EC array probe 240. Plot 380 shows voltage levels detected as an EC array probe (not shown in FIG. 8) moves across component 370. Plot 390 is produced after compensation 288 is applied (described above with respect to FIG. 5) to the raw test image of plot 380 by a processing device (not shown in FIG. 8). In the exemplary embodiments, after compensation for the possible defect orientations is performed as described above, a first area of interest 392 and a second area of interest 394 are apparent. Once the data forming plot 390 is compared to the calculated threshold value corresponding to a predetermined PoD, first area of interest 392 is no longer identified as a potential component defect. In plot 400, only second area of interest 394 remains, which corresponds to the only defect 372 present in component 370.

In summary, the ADR process described herein facilitates the identification and segmentation of the flaw responses amidst various forms of electronic noise and part geometry indications using an adaptive thresholding scheme. Flaws of different orientations respond differently to the WASP array, both in terms of maximum amplitude of the response and in terms of its signature. The ADR process performs a compensation of image data corresponding to various flaw orientations to facilitate maximizing the extracted probe response. Once segmented, the flaw orientation is estimated in order to extract the appropriate maximum response.

As described above, the ADR process does not require prior information in the form of look-up tables, threshold values, or reference images. The image processing with the use of the wavelet decomposition has improved small crack detection, which facilitates improved PoD. The algorithm decomposes the image into various frequency sub-bands in the wavelet domain. The sub-bands are then subjected to a cascade of noise filters and adaptive thresholds, which are customized to the signal content of the sub-band under consideration. The use of appropriate sub-bands offers the advantage of enhancing the flaw response signature, while not simultaneously enhancing a level of noise, thereby facilitating improving a signal to noise ratio (SNR), detectability, and reducing the possibilities of false positives. This provides improvement over the conventional rigid threshold segmentation schemes on the raw data.

The compensation schemes apart from maximizing flaw responses, can estimate orientation of the flaw segmented. The peak-to-peak response is calculated for each region. Based on the orientation, the appropriate compensation is applied to facilitate deriving a maximum flaw response.

Improved defect characterization capability has been achieved by using a multivariate linear transformation to predict equivalent defect size. The multivariate equation is derived from regression analyses of various features extracted from the segmented region. The features used include maximum amplitude, number and polarity of peaks, energy of the segment and other derived features. Based on these features a transfer function has been developed that directly predicts the equivalent size of the detected defect.

By providing small flaw detection ability and reduced false positives, ADR process consequently improves the PoD. Use of the appropriate wavelet facilitates enhancing the flaw signature, while suppressing noise. Reductions in false identification of defects directly impact the First Time Yield (FTY) of the inspection. A poor FTY can negate any advantages WASP might provide in terms of inspection time.

Exemplary embodiments of eddy current inspection processes and systems are described above in detail. The processes and systems are not limited to the specific embodiments described herein, but rather, components of each system may be utilized independently and separately from other components described herein. Each system component can also be used in combination with other system components. More specifically, although the processes and systems herein are described with respect to inspection of aircraft engine components, it should be appreciated that the processes and systems can also be applied to a wide variety of components used within a steam turbine, a nuclear power plant, an automotive engine, or to inspect any mechanical component.

While the invention has been described in terms of various specific embodiments, those skilled in the art will recognize that the invention can be practiced with modification within the spirit and scope of the claims.

1. A method for testing a component using an eddy current array probe, said method comprising:
calibrating the eddy current array probe;
collecting data from the eddy current array probe for analysis; and
processing the collected data to at least one of compensate for response variations due to a detected orientation of a detected imperfection and to facilitate minimizing noise.

2. A method according to claim 1 further comprising analyzing the processed data to identify a potential imperfection in the component.

3. A method according to claim 1 further comprising:
estimating a size of the detected imperfection; and
calculating a threshold value based on a predetermined probability of detection.

4. A method according to claim 3 further comprising comparing the estimated size of the detected imperfection to the calculated threshold value to facilitate limiting false identifications of imperfections.

5. A method according to claim 1, wherein data collection and processing is automatically performed by an eddy current flaw detection system.

6. A method according to claim 1, wherein calibrating the eddy current array probe comprises:
configuring a plurality of test notches in a calibration block; and
calculating an eddy current array probe gain, for use in testing the component, based on measurements taken by the eddy current array probe while testing the calibration block.

7. A method according to claim 1, wherein processing the collected data to compensate for response variations comprises:
determining an orientation of a detected imperfection by analyzing a plurality of partial defect responses; and
producing a single maximum defect response from the plurality of partial defect responses.

8. A method according to claim 7, wherein producing a single maximum defect response from the plurality of partial defect responses comprises calculating a maximum voltage from the plurality of partial defect responses when a circumferential imperfection is detected.

9. A method according to claim 7, wherein producing a single maximum defect response from the plurality of partial defect responses comprises calculating a sum of the plurality of partial defect responses when a radial imperfection is detected.

10. An eddy current flaw detection system comprising:
an eddy current array probe; and
a processing device coupled to said eddy current array probe, said processing device configured to collect data from said eddy current array probe and compensate collected data for varying orientations of detected imperfections.

11. An eddy current flaw detection system according to claim 10, wherein said processing device is further configured to analyze the collected data to determine the orientation of detected imperfections.

12. An eddy current flaw detection system according to claim 10, wherein said processing device is further configured to:
estimate a size of the detected imperfection; and
to compare the estimated size to a predetermined threshold to limit false determinations of imperfections.

13. An eddy current array probe calibration device comprising:
a plurality of test notches oriented in a plurality of rows and columns, wherein adjacent rows are separated by a predetermined distance, and wherein adjacent columns are separated by a predetermined distance; and
a voltage measuring device configured to measure a sensed voltage detected by said eddy current array probe at each of said plurality of notches.

14. A calibration device according to claim 13 further comprising a processing device configured to calculate an eddy current probe gain from the measured voltages to be used when testing a component.

15. A method of calibrating an eddy current array probe, said method comprising:
positioning a plurality of notches in a predetermined manner on a test block;
measuring a voltage sensed by the eddy current array probe for each of said plurality of notches; and
setting a gain of the eddy current array probe based on the measured voltage.
